(19) United States
(12) Patent Application Publication
(10) Pub. No.: US 2025/0183086 A1
(43) Pub. Date: Jun. 5, 2025

(54) ELECTROSTATIC CHUCK AND SUBSTRATE PROCESSING APPARATUS

(71) Applicant: Tokyo Electron Limited, Tokyo (JP)

(72) Inventor: Yasuharu SASAKI, Miyagi (JP)

(73) Assignee: Tokyo Electron Limited, Tokyo (JP)

(21) Appl. No.: 19/052,558

(22) Filed: Feb. 13, 2025

Related U.S. Application Data
(63) Continuation of application No. PCT/JP2023/028684, filed on Aug. 7, 2023.

(30) Foreign Application Priority Data
Aug. 16, 2022 (JP) 2022-129740

(51) Int. Cl. H01L 21/683; H01J 37/32

(52) U.S. Cl. CPC H01L 21/6833; H01J 37/32091; H01J 37/32715

(57) ABSTRACT

An electrostatic chuck comprising: a dielectric layer having a substrate supporting surface, the substrate supporting surface having a plurality of dot-shaped protrusions and an annular protrusion surrounding the plurality of dot-shaped protrusions, the annular protrusion having an inner circumferential wall and an outer circumferential wall, the inner circumferential wall extending over an entire circumference along a first circle in plan view, the outer circumferential wall having a circular arc portion extending along a part of a second circle lager than the first circle in plan view, and a cutout portion extending linearly between both ends of the circular arc portion in plan view; and a chuck electrode layer disposed in the dielectric layer to overlap the annular protrusion over an entire circumference in plan view.

### CROSS-REFERENCE TO RELATED APPLICATIONS

This application is a bypass continuation application of International Application No. PCT/JP2023/028684 having an international filing date of Aug. 7, 2023 and designating the United States, the International Application being based upon and claiming the benefit of priority from Japanese Patent Application No. 2022-129740 filed on Aug. 16, 2022, the entire contents of each are incorporated herein by reference.

### TECHNICAL FIELD

The present disclosure relates to an electrostatic chuck and a substrate processing apparatus.

### BACKGROUND

Japanese Laid-open Patent Publication No. 2012-234904 discloses an electrostatic chuck for electrostatically attracting a substrate to be subjected to dry etching, the electrostatic chuck including a substrate holder having an electrostatic attracting surface of which shape is similar to that of the substrate, the substrate holder having an annular groove formed along the edge of the electrostatic attracting surface, a recess formed along the annular groove at a part of the electrostatic attracting surface surrounded by the annular groove, a first introducing hole formed at the center of the bottom surface of the recess to introduce a heat transfer gas into the recess, and a plurality of second introducing holes formed along the edge of the bottom surface of the recess to introduce a heat transfer gas into the recess.

Japanese Laid-open Patent Publication No. 2015-88743 discloses an electrostatic chuck including: a ceramic dielectric substrate, which is a polycrystalline ceramic sintered body, having a first main surface on which an object to be processed is placed and a second main surface opposite to the first main surface; and an electrode layer, which is interposed between the first main surface and the second main surface of the ceramic dielectric substrate and sintered integrally with the ceramic dielectric substrate, the electrode layer including a plurality of electrode elements spaced apart from one another, the outer periphery of the ceramic dielectric substrate being processed such that the distance between the outer periphery of the ceramic dielectric substrate and the outer periphery of the electrode layer becomes uniform in a direction perpendicular to the first main surface, and the distance between the outer periphery of the electrode layer and the outer periphery of the ceramic dielectric substrate in the direction perpendicular to the first main surface is less than the distance between the plurality of electrode elements.

### SUMMARY

In one aspect, the present disclosure provides an electrostatic chuck and a substrate processing apparatus that improves in-plane uniformity of a temperature of a substrate.

According to an exemplary embodiment, an electrostatic chuck is provided. The electrostatic chuck comprises a dielectric layer having a substrate supporting surface, the substrate supporting surface having a plurality of dot-shaped protrusions and an annular protrusion surrounding the plurality of dot-shaped protrusions, the annular protrusion having an inner circumferential wall and an outer circumferential wall, the inner circumferential wall extending over an entire circumference along a first circle in plan view, the outer circumferential wall having a circular arc portion extending along a part of a second circle lager than the first circle in plan view, and a cutout portion extending linearly between both ends of the circular arc portion in plan view; and a chuck electrode layer disposed in the dielectric layer to overlap the annular protrusion over an entire circumference in plan view.

### BRIEF DESCRIPTION OF THE DRAWINGS

FIG. 1 is an example of a diagram for explaining an example of a configuration of a capacitively coupled plasma processing apparatus.

FIG. 2 is an example of a top view of an electrostatic chuck according to a first embodiment.

FIG. 3 is an example of a partially enlarged cross-sectional view of a main body of a substrate support.

FIG. 4 is an example of a top view of an electrostatic chuck according to a reference example.

FIG. 5 is an example of an analysis result of temperature distribution of a substrate supported by the electrostatic chuck according to the first embodiment.

FIG. 6 is an example of an analysis result of temperature distribution of a substrate supported by the electrostatic chuck according to the reference example.

FIG. 7 is an example of an analysis result of temperature distribution of a substrate supported by an electrostatic chuck.

FIG. 8 is an example of an analysis result of temperature distribution of a substrate supported by an electrostatic chuck.

FIG. 9 is an example of a partially enlarged top view of the electrostatic chuck according to the first embodiment.

FIG. 10 is an example of a partially enlarged top view of an electrostatic chuck according to a second embodiment.

FIG. 11 is an example of a partially enlarged top view of an electrostatic chuck according to a third embodiment.

FIG. 12 is an example of a partially enlarged top view of an electrostatic chuck according to a fourth embodiment.

FIG. 13 is an example of a partially enlarged top view of an electrostatic chuck according to a fifth embodiment.

### DETAILED DESCRIPTION

Hereinafter, various exemplary embodiments will be described in detail with reference to the accompanying drawings. Further, like reference numerals will be used for like or corresponding parts throughout the drawings.

### (Plasma Processing System)

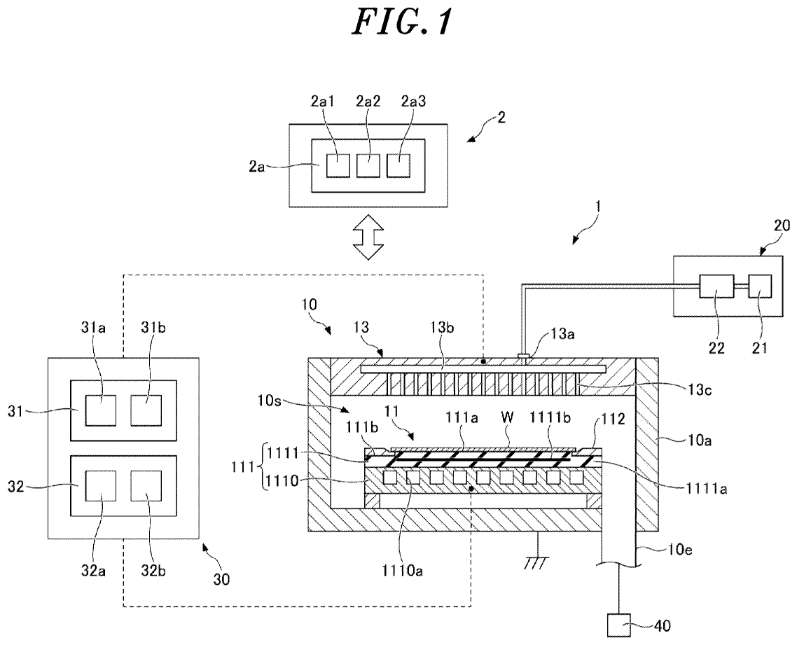

Hereinafter, an example of a configuration of a plasma processing system will be described. FIG. 1 is an example of a diagram for explaining an example of a configuration of a capacitively coupled plasma processing apparatus (substrate processing apparatus) 1.

The plasma processing system includes the capacitively coupled plasma processing apparatus 1 and a controller 2. The capacitively coupled plasma processing apparatus 1 includes a plasma processing chamber 10, a gas supply 20, a power supply 30, and an exhaust system 40. The plasma processing apparatus 1 further includes a substrate support 11 and a gas introducing unit. The gas introducing unit is configured to introduce at least one processing gas into the plasma processing chamber 10. The gas introducing unit includes a showerhead 13. The substrate support 11 is disposed in the plasma processing chamber 10.

The showerhead 13 is disposed above the substrate support 11. In one embodiment, the showerhead 13 constitutes at least a part of the ceiling of the plasma processing chamber 10. The plasma processing chamber 10 has a plasma processing space 10s defined by the showerhead 13, a sidewall 10a of the plasma processing chamber 10, and the substrate support 11. The plasma processing chamber 10 has at least one gas inlet for supplying at least one processing gas to the plasma processing space 10s and at least one gas outlet for exhausting a gas from the plasma processing space 10s. The plasma processing chamber 10 is grounded. The showerhead 13 and the substrate support 11 are electrically insulated from the housing of the plasma processing chamber 10.

The substrate support 11 includes a main body 111 and a ring assembly 112. The main body 111 has a central region 111a for supporting a substrate W and an annular region 111b for supporting the ring assembly 112. A wafer is an example of a substrate W. The annular region 111b of the main body 111 surrounds the central region 111a of the main body 111 in plan view. The substrate W is disposed on the central region 111a of the main body 111, and the ring assembly 112 is disposed on the annular region 111b of the main body 111 to surround the substrate W on the central region 111a of the main body 111. Thus, the central region 111a is also referred to as a substrate supporting surface for supporting the substrate W, and the annular region 111b is also referred to as a ring supporting surface for supporting the ring assembly 112.

In one embodiment, the main body 111 includes a base 1110 and an electrostatic chuck 1111. The base 1110 includes a conductive member. The conductive member of the base 1110 can function as a lower electrode. The electrostatic chuck 1111 is disposed on the base 1110. The electrostatic chuck 1111 includes a ceramic member (dielectric layer) 1111a and an electrostatic electrode (also referred to as an electrostatic electrode layer, electrostatic chuck electrode layer, or chuck electrode layer) 1111b disposed in the ceramic member 1111a. The ceramic member 1111a has a central region 111a. In one embodiment, the ceramic member 1111a also has an annular region 111b. Another member surrounding the electrostatic chuck 1111, such as an annular electrostatic chuck or an annular insulating member, may have the annular region 111b. In this case, the ring assembly 112 may be disposed on either the annular electrostatic chuck or the annular insulating member, or may be disposed on both the electrostatic chuck 1111 and the annular insulating member. In addition, at least one RF/DC electrode connected to a radio frequency (RF) power supply 31 and/or a direct current (DC) power supply 32, which will be described later, may be disposed in the ceramic member 1111a. In this case, at least one RF/DC electrode functions as a lower electrode. When a bias RF signal and/or a DC signal, which will be described later, is supplied to the at least one RF/DC electrode, the RF/DC electrode is also called a bias electrode. Note that the conductive member of the base 1110 and at least one RF/DC electrode may function as a plurality of lower electrodes. Further, the electrostatic electrode 1111b may function as the lower electrode. Thus, the substrate support 11 includes at least one lower electrode.

The ring assembly 112 includes one or more annular members. In one embodiment, one or more annular members include one or more edge rings and at least one cover ring. The edge ring is made of a conductive material or an insulating material, and the cover ring is made of an insulating material.

Further, the substrate support 11 may include a temperature control module configured to adjust at least one of the electrostatic chuck 1111, the ring assembly 112, and the substrate W to a target temperature. The temperature control module may include a heater, a heat transfer medium, a channel 1110a, or a combination thereof. A heat transfer fluid such as brine or a gas flows through the channel 1110a. In one embodiment, the channel 1110a is formed in the base 1110, and one or more heaters are disposed in the ceramic member 1111a of the electrostatic chuck 1111. Further, the substrate support 11 may include a heat transfer gas supply configured to supply a heat transfer gas to a gap between the backside of the substrate W and the central region 111a.

The showerhead 13 is configured to introduce at least one processing gas from the gas supply 20 into the plasma processing space 10s. The showerhead 13 has at least one gas supply port 13a, at least one gas diffusion space 13b, and a plurality of gas inlet ports 13c. The processing gas supplied to the gas supply port 13a passes through the gas diffusion space 13b and is introduced into the plasma processing space 10s from the plurality of gas inlet ports 13c. Further, the showerhead 13 includes at least one upper electrode. In addition to the showerhead 13, the gas introducing unit may include one or more side gas injectors (SGI) attached to one or more openings formed in the sidewall 10a.

The gas supply 20 may include at least one gas source 21 and at least one flow controller 22. In one embodiment, the gas supply 20 is configured to supply at least one processing gas from the corresponding gas source 21 to the showerhead 13 via the corresponding flow controller 22. The flow controllers 22 may include, e.g., a mass flow controller or a pressure-controlled flow controller. Further, the gas supply 20 may include one or more flow modulation devices for modulating the flow of at least one processing gas or causing it to pulsate.

The power supply 30 includes an RF power supply 31 connected to the plasma processing chamber 10 via at least one impedance matching circuit. The RF power supply 31 is configured to supply at least one RF signal (RF power) to at least one lower electrode and/or at least one upper electrode. Accordingly, plasma is produced from at least one processing gas supplied to the plasma processing space 10s. Thus, the RF power supply 31 can function as at least a part of a plasma generator configured to produce plasma from one or more processing gases in the plasma processing chamber 10. Further, by supplying a bias RF signal to the at least one lower electrode, a bias potential is generated at the substrate W, and ion components in the produced plasma can be attracted to the substrate W.

In one embodiment, the RF power supply 31 includes a first RF generator 31a and a second RF generator 31b. The first RF generator 31a is connected to the at least one lower electrode and/or the at least one upper electrode via at least one impedance matching circuit, and is configured to generate a source RF signal (source RF power) for plasma generation. In one embodiment, the source RF signal has a frequency within a range of 10 MHz to 150 MHz. In one embodiment, the first RF generator 31a may be configured to generate a plurality of source RF signals having different frequencies. The generated one or more source RF signals are provided to at least one lower electrode and/or at least one upper electrode.

The second RF generator 31b is connected to at least one lower electrode via at least one impedance matching circuit and configured to generate a bias RF signal (bias RF power). The frequency of the bias RF signal may be the same as or different from the frequency of the source RF signal. In one embodiment, the bias RF signal has a frequency lower than the frequency of the source RF signal. In one embodiment, the bias RF signal has a frequency within a range of 100 kHz to 60 MHz. In one embodiment, the second RF generator 31b may be configured to generate a plurality of bias RF signals having different frequencies. The generated one or more bias RF signals are provided to at least one lower electrode. Further, in various embodiments, at least one of the source RF signal and the bias RF signal may pulsate.

Further, the power supply 30 may include a DC power supply 32 connected to the plasma processing chamber 10. The DC power supply 32 includes a first DC generator 32a and a second DC generator 32b. In one embodiment, the first DC generator 32a is connected to at least one lower electrode and configured to generate a first DC signal. The generated first bias DC signal is applied to the at least one lower electrode. In one embodiment, the second DC generator 32b is connected to at least one upper electrode and configured to generate a second DC signal. The generated second DC signal is applied to the at least one upper electrode.

In various embodiments, at least one of the first and second DC signals may pulsate. In this case, a sequence of voltage pulses is applied to the at least one lower electrode and/or at least one upper electrode. The voltage pulse may have a rectangular pulse waveform, a trapezoidal pulse waveform, a triangular pulse waveform, or a combination thereof. In one embodiment, a waveform generator for generating a sequence of voltage pulses from a DC signal is connected between the first DC generator 32a and at least one lower electrode. Thus, the first DC generator 32a and the waveform generator constitute a voltage pulse generator. When the second DC generator 32b and the waveform generator constitute a voltage pulse generator, the voltage pulse generator is connected to at least one upper electrode. The voltage pulse may have positive polarity or negative polarity. The sequence of voltage pulses may include one or more positive voltage pulses and one or more negative voltage pulses in one cycle. The first and second DC generators 32a and 32b may be provided in addition to the RF power supply 31, or the first DC generator 32a may be provided instead of the second RF generator 31b.

The exhaust system 40 may be connected to a gas exhaust port 10e provided at the bottom portion of the plasma processing chamber 10, for example. The exhaust system 40 may include a pressure control valve and a vacuum pump. The pressure in the plasma processing space 10s is adjusted by the pressure control valve. The vacuum pump may include a turbomolecular pump, a dry pump, or a combination thereof.

The controller 2 processes computer-executable instructions that cause the plasma processing apparatus 1 to execute various steps described in the present disclosure. The controller 2 may be configured to control individual elements of the plasma processing apparatus 1 to execute various steps described herein. In one embodiment, the controller 2 may be partially or entirely included in the plasma processing apparatus 1. The controller 2 may include a processing part 2a1, a storage part 2a2, and a communication interface 2a3. The controller 2 is realized by, e.g., a computer 2a. The processing part 2a1 may be configured to read a program from the storage part 2a2, and perform various control operations by executing the read program. The program may be stored in advance in the storage part 2a2, or may be acquired via a medium when necessary. The acquired program is stored in the storage part 2a2, and is read out from the storage part 2a2 and executed by the processing part 2a1. The medium may be various storage media readable by the computer 2a, or may be a communication line connected to the communication interface 2a3. The processing part 2a1 may be a central processing unit (CPU). The storage part 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

### (Electrostatic Chuck 1111)

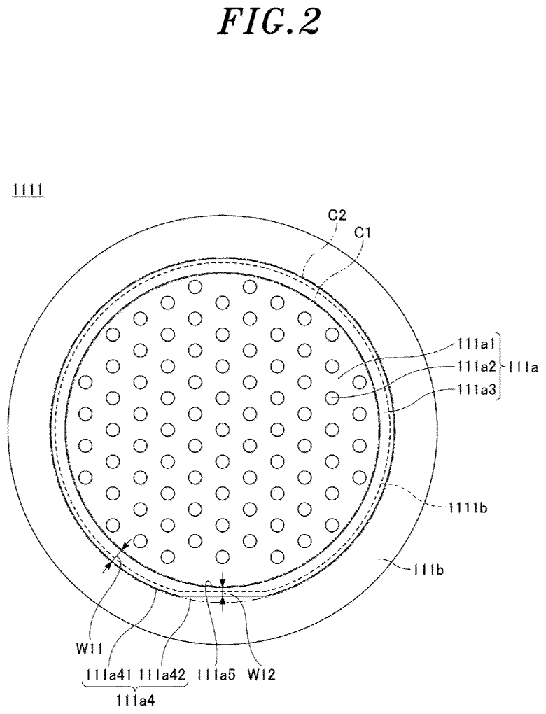

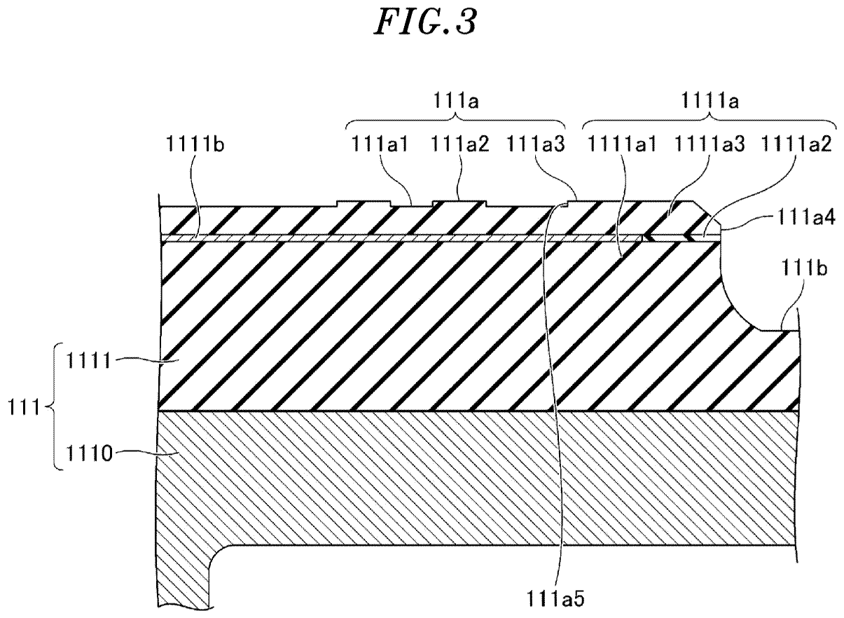

Next, the electrostatic chuck 1111 according to the first embodiment will be described with reference to FIGS. 2 and 3. FIG. 2 is an example of a top view of the electrostatic chuck 1111 according to the first embodiment. FIG. 3 is an example of a partially enlarged cross-sectional view of the main body 111 of the substrate support 11.

The ceramic member (dielectric layer) 1111a (see FIG. 1) of the electrostatic chuck 1111 has a substrate supporting surface (the central region 111a) for supporting the substrate W and a ring supporting surface (the annular region 111b) for supporting the ring assembly 112. Further, the substrate supporting surface (the central region 111a) of the electrostatic chuck 1111 has a recessed surface 111a1, a plurality of dot-shaped protrusions 111a2, and an annular protrusion 111a3 surrounding the dot-shaped protrusions 111a2. The dot-shaped protrusions 111a2 are an example of a plurality of protrusions scattered in the annular protrusion 111a3.

The recessed surface 111a1 is a surface that is recessed deeper than the upper surface (the surface to be in contact with the backside of the substrate W) of the dot-shaped protrusions 111a2 and the upper surface (the surface to be in contact with the backside of the substrate W) of the annular protrusion 111a3. Further, the recessed surface 111a1 faces the backside of the substrate W while being spaced apart from the backside of the substrate W when the substrate W is placed on the electrostatic chuck 1111. Further, the recessed surface 111a1 may be provided with an opening (not shown) for discharging a heat transfer gas such as He gas supplied from a heat transfer gas supply.

Further, the substrate supporting surface (the central region 111a) of the electrostatic chuck 1111 has the dot-shaped protrusions 111a2 and the annular protrusions 111a3 protruding to a position above the recessed surface 111a1.

The dot-shaped protrusions 111a2 are formed in a substantially cylindrical shape protruding from the recessed surface 111a1. The upper surfaces of the dot-shaped protrusions 111a2 have a circular shape or the like. When the electrostatic chuck 1111 is viewed from the top (see FIG. 2), the plurality of dot-shaped protrusions 111a2 are formed at the inner side of the annular protrusion 111a3 having a circular ring shape. When the substrate W is placed on the electrostatic chuck 1111, the upper surfaces of the dot-shaped protrusions 111a2 are brought into contact with the backside of the substrate W to support the substrate W. The shape (size), arrangement, and number of the dot-shaped protrusions 111a2 shown in FIG. 2 are merely examples, and are not limited thereto.

The annular protrusion 111a3 protrudes from the recessed surface 111a1, and is formed in a circular ring shape along the outer periphery of the central region 111a. When the substrate W is placed on the electrostatic chuck 1111, the upper surface of the annular protrusion 111a3 is brought into contact with the backside of the substrate W to support the substrate W.

Further, then the substrate W is supported by the electrostatic chuck 1111, a space (gap) is formed by the backside of the substrate W, the recessed surface 111a1 of the electrostatic chuck 1111, and the inner circumferential wall 111a5 of the annular protrusion 111a3. The heat transfer gas supply supplies the heat transfer gas to the space (gap) through an opening formed in the recessed surface 111a1. Further, the annular protrusion 111a3 is brought into contact with the outer edge of the backside of the substrate W and becomes in close contact therewith by electrostatic attraction, thereby functioning as a seal band that seals the heat transfer gas.

Further, the annular protrusion 111a3 has an outer circumferential wall 111a4 and an inner circumferential wall 111a5. The outer circumferential wall 111a4 is formed from the outer peripheral end of the upper surface (the supporting surface of the substrate W) of the annular protrusion 111a3 to the ring supporting surface (the annular region 111b). The inner circumferential wall 111a5 is formed from the inner peripheral end of the upper surface (the supporting surface of the substrate W) of the annular protrusion 111a3 to the recessed surface 111a1.

The outer circumferential wall 111a4 has a circular arc portion 111a41, which is a part of a circle in plan view, and a cutout portion (linear portion) 111a42 that is linearly cut out from the circle in plan view. Here, the substrate W has an orientation flat for indicating the crystal orientation. Therefore, in the example shown in FIG. 2, the cutout portion 111a42 that is linearly cut out from the circle in plan view is formed at the outer peripheral portion of the substrate supporting surface that supports the substrate W to correspond to the orientation flat of the substrate W.

On the other hand, the inner circumferential wall 111a5 is formed in a circular shape over the entire circumference in plan view. In one embodiment, the inner circumferential wall 111a5 extends along the entire circumference of a first circle C1 in plan view. In one embodiment, the outer circumferential wall 111a4 has the circular arc portion 111a41 extending along a part of the second circle C2 larger than the first circle C1 in plan view, and the cutout portion 111a42 extending linearly between both ends of the circular arc portion 111a41 in plan view. In plan view, the first circle C1 and the inner circumferential wall 111a5 overlap, but in FIG. 2, the first circle C1 indicated by the dashed double-dotted line is shifted radially inward. Further, in plan view, the second circle C2 and the circular arc portion 111a41 of the outer circumferential wall 111a4 overlap, but in FIG. 2, the second circle C2 indicated by the dashed double-dotted line is shifted radially outward.

Further, the annular protrusion 111a3 has a first width W11 from the outer circumferential wall 111a4 to the inner circumferential wall 111a5 in the circular arc portion 111a41. In other words, the first width W11 is a radial width between the outer circumferential wall 111a4 and the inner circumferential wall 111a5. In the circular arc portion 111a41, the first width W11 is constant.

Further, the annular protrusion 111a3 has a second width W12 from the outer circumferential wall 111a4 to the inner circumferential wall 111a5 in the central region in the circumferential direction of the cutout portion 111a42. In other words, the second width W12 is a radial width between the outer circumferential wall 111a4 and the inner circumferential wall 111a5.

Further, in the cutout portion 111a42, the radial width between the outer circumferential wall 111a4 and the inner circumferential wall 111a5 becomes gradually smaller (decreases) from the outer region in the circumferential direction of the cutout portion 111a42 toward the central region in the circumferential direction of the cutout portion 111a42. Further, in the central region in the circumferential direction of the cutout portion 111a42, the radial width between the outer circumferential wall 111a4 and the inner circumferential wall 111a5 has the second width W12 that is the minimum value.

Further, the first width W11 is greater than the second width W12. Specifically, the first width W11 is preferably within a range of 1 to 10 times the second width W12. Further, the first width W11 is preferably within a range of 1 mm to 10 mm.

The electrostatic electrode 1111b is disposed in the ceramic member (dielectric layer) 1111a (see FIG. 1). As shown in FIG. 3, the ceramic member 1111a has a lower ceramic member 1111a1, an intermediate annular ceramic member 1111a2, and an upper ceramic member 1111a3. The lower ceramic member 1111a1 is disposed below the electrostatic electrode 1111b. The upper ceramic member 1111a3 is disposed on the electrostatic electrode 1111b. The intermediate annular ceramic member 1111a2 surrounds the electrostatic electrode 1111b, and is disposed between the upper ceramic member 1111a3 and the lower ceramic member 1111a1. Further, the ceramic member 1111a may be formed integrally. Further, the lower ceramic member 1111a1, the intermediate annular ceramic member 1111a2, and the upper ceramic member 1111a3 may be made of the same material or different materials. Further, the electrostatic electrode 1111b is provided at a position higher than the ring supporting surface (the annular region 111b) and lower than the recessed surface 111a1 of the substrate supporting surface (the central region 111a).

As shown in FIG. 2, the electrostatic electrode 1111b has a substantially circular shape in plan view, and the outer edge of the electrostatic electrode 1111b is disposed radially outward from the inner circumferential wall 111a5 and radially inward from the outer circumferential wall 111a4 in plan view. Therefore, the electrostatic electrode (chuck electrode layer) 1111b is disposed in the ceramic member (dielectric layer) 1111a to overlap the annular protrusion 111a3 over the entire circumference in plan view. Accordingly, the outer edge of the backside of the substrate W is attracted over the entire circumference. Therefore, the outer edge of the backside of the substrate W is brought into close contact with the upper surface of the annular protrusion 111a3 over the entire circumference, thereby sealing the heat transfer gas.

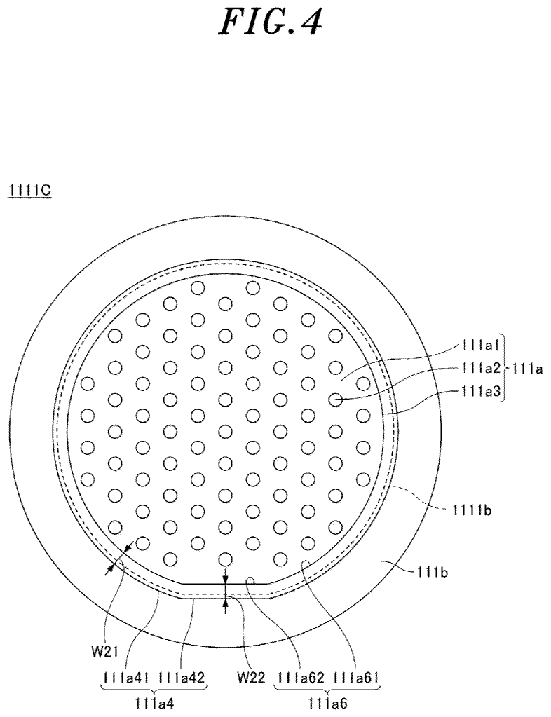

Here, an electrostatic chuck 1111C according to a reference example will be described with reference to FIG. 4. FIG. 4 is an example of a top view of the electrostatic chuck 1111C according to the reference example.

The electrostatic chuck 1111C according to the reference example shown in FIG. 4 is different from the electrostatic chuck 1111 according to the first embodiment shown in FIG. 2 in the shape of the annular protrusion 111a3. The other configurations are the same, so that the redundant description thereof will be omitted.

Further, the annular protrusion 111a3 of the electrostatic chuck 1111C according to the reference example has an outer circumferential wall 111a4 and an inner circumferential wall 111a6. The outer circumferential wall 111a4 has the circular arc portion 111a41 that is a part of a circle in plan view, and the cutout portion 111a42 that is cut out from the circle in plan view. The inner circumferential wall 111a6 has a circular arc portion 111a61 that is a part of a circle in plan view, and a linear portion 111a62 that is cut out from the circle in plan view.

The annular protrusion 111a3 has a third width W21, which is the width between the circular arc portion 111a41 of the outer circumferential wall 111a4 and the circular arc portion 111a61 of the inner circumferential wall 111a6, at the circular arc portion 111a41. Further, the annular protrusion 111a3 has a fourth width W22, which is the radial width between the cutout portion 111a42 of the outer circumferential wall 111a4 and the linear portion 111a62 of the inner circumferential wall 111a6, at the central region in the circumferential direction of the cutout portion 111a42. Further, the third width W21 and the fourth width W22 are the same. In other words, the radial width of the upper surface of the annular protrusion 111a3 is constant over the entire circumference.

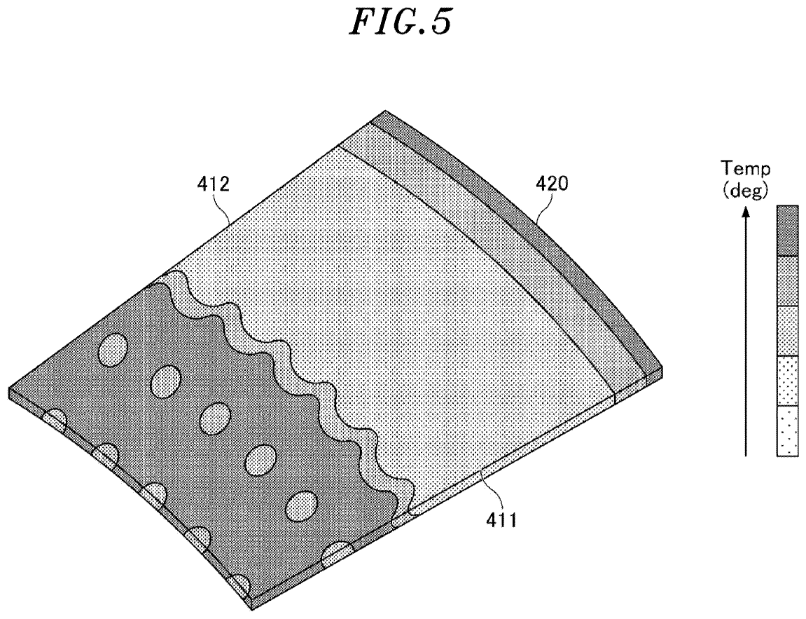

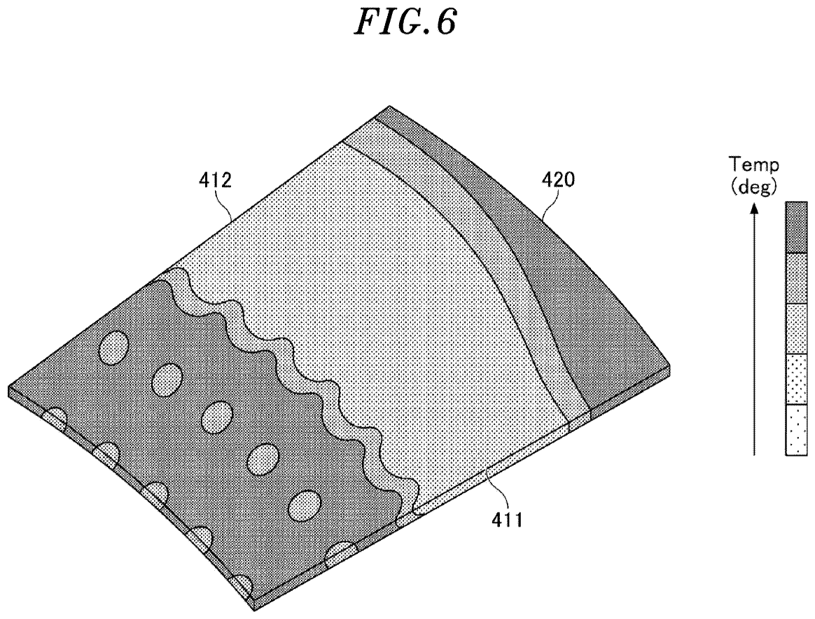

Next, the in-plane temperature uniformity of the substrate W will be described with reference to FIGS. 5 to 8. FIG. 5 is an example of an analysis result of the temperature distribution of the substrate W supported by the electrostatic chuck 1111 according to the first embodiment. FIG. 6 is an example of an analysis result of the temperature distribution of the substrate W supported by the electrostatic chuck 1111C according to the reference example. Here, plasma is produced in the plasma processing space 10s, and heat is inputted from the plasma to the substrate W. Further, the analysis result of the temperature of the substrate W, which is obtained when heat dissipates from the substrate W to the substrate support 11, is illustrated as an example. Further, in FIGS. 5 and 6, the temperature of the substrate W is illustrated by the shade of dot hatching. As indicated by the arrows in FIGS. 5 and 6, the temperature becomes higher as the dot hatching becomes darker. Further, FIGS. 5 and 6 show examples of the analysis results in a region near the central region in the circumferential direction of the cutout portion 111a42 from the center of substrate W in the circumferential direction of the substrate W, where the distance from the center of the substrate W in the radial direction of substrate W is within a range of 125 mm to 150 mm. In other words, in FIGS. 5 and 6, a boundary line 411 is a line that passes through the central region of the cutout portion 111a42 in the circumferential direction from the center of substrate W. Further, the boundary line 412 is a line that passes through the circular arc portion 111a41 from the center of the substrate W. The boundary line 420 indicates the outer periphery of the substrate W. In the analysis, the substrate W has a circular shape without an orientation flat.

Next, the substrate W supported by the electrostatic chuck 1111 according to the reference example will be described. In a state where the substrate W is attracted to the electrostatic chuck 1111, the contact pressure between the substrate W and the electrostatic chuck 1111 becomes high at the position where the substrate W is brought into contact with the upper surfaces of the dot-shaped protrusions 111a2 and on the inner peripheral side of the upper surface of the annular protrusion 111a3 (near the edge of the upper surface of the annular protrusion 111a3 and the inner circumferential wall 111a5). Further, as shown in FIG. 4, in the electrostatic chuck 1111C according to the reference example, the linear portion 111a62 is formed radially inward from the circular arc portion 111a61. Accordingly, as shown in FIG. 6, a region where the temperature increases on the outer peripheral side of the substrate W is formed near the cutout portion 111a42 of the annular protrusion 111a3 (near the boundary line 411). In other words, as can be seen from comparison between the temperature distribution on the boundary line 411 and the temperature distribution on the boundary line 412, the temperature uniformity in the circumferential direction is poor at the outer periphery of the substrate W.

Next, the substrate W supported by the electrostatic chuck 1111 according to the first embodiment will be described. In a state where the substrate W is attracted to the electrostatic chuck 1111, the contact pressure between the substrate W and the electrostatic chuck 1111 increases at the position where the substrate W is brought into contact with the upper surfaces of the dot-like protrusions 111a2 and on the inner peripheral side of the upper surface of the annular protrusion 111a3 (near the edge of the upper surface of the annular protrusion 111a3 and the inner circumferential wall 111a5). Further, as shown in FIG. 2, the inner circumferential wall 111a5 of the electrostatic chuck 1111 according to the first embodiment is formed in a circular shape. Accordingly, as can be seen from the comparison between the temperature distribution on the boundary line 411 and the temperature distribution on the boundary line 412 in FIG. 5, the temperature uniformity in the circumferential direction is improved.

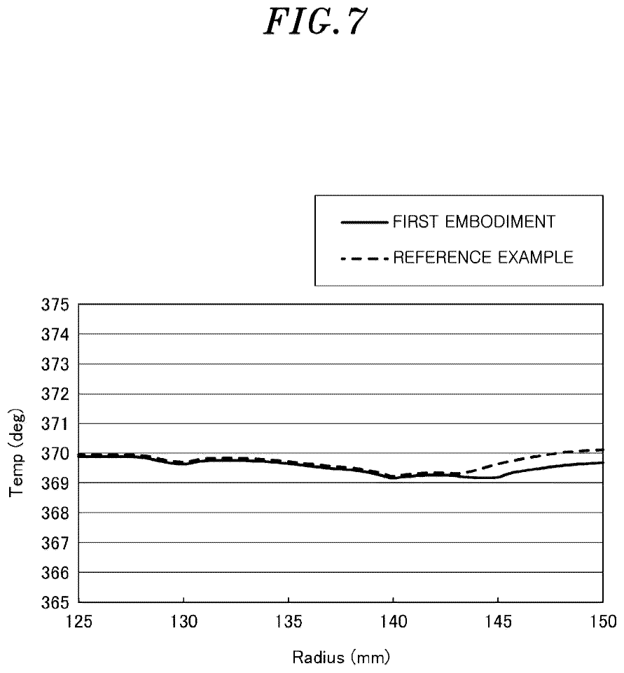

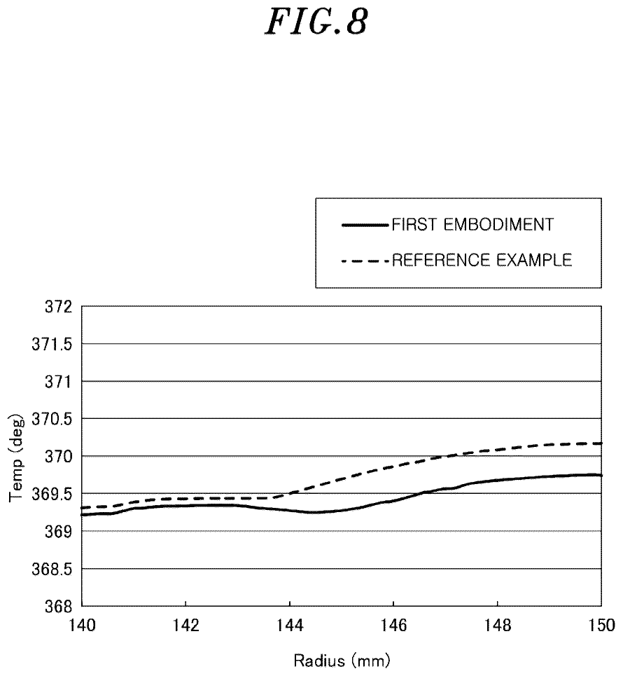

FIGS. 7 and 8 are examples of the analysis results of the temperature distribution of the substrate W supported by the electrostatic chucks 1111 and 1111C. FIGS. 7 and 8 illustrate the temperature distribution of the substrate W on the line (the boundary line 411 shown in FIGS. 5 and 6) passing through the central region in the circumferential direction of the cutout portion 111a42 from the center of the substrate W. In other words, the horizontal axis represents a radial distance (Radius (mm)) from the center of the substrate W. The vertical axis represents a temperature (Temp (deg)). Further, an example of the temperature distribution of the substrate W supported by the electrostatic chuck 1111 according to the first embodiment is indicated by a solid line. An example of the temperature distribution of the substrate W supported by the electrostatic chuck 1111C according to the reference example is indicated by a dashed line. FIG. 7 is a graph showing a range of the radial distance from 125 mm to 150 mm, which is analyzed in FIGS. 5 and 6. FIG. 8 is a graph in which the range of the radial distance from 140 mm to 150 mm in FIG. 7 is enlarged.

As shown in FIG. 7 and FIG. 8, in the electrostatic chuck 1111 according to the first embodiment, the temperature increase on the outer peripheral side can be suppressed at the orientation flat of the substrate W, compared to the electrostatic chuck 1111C according to the reference example.

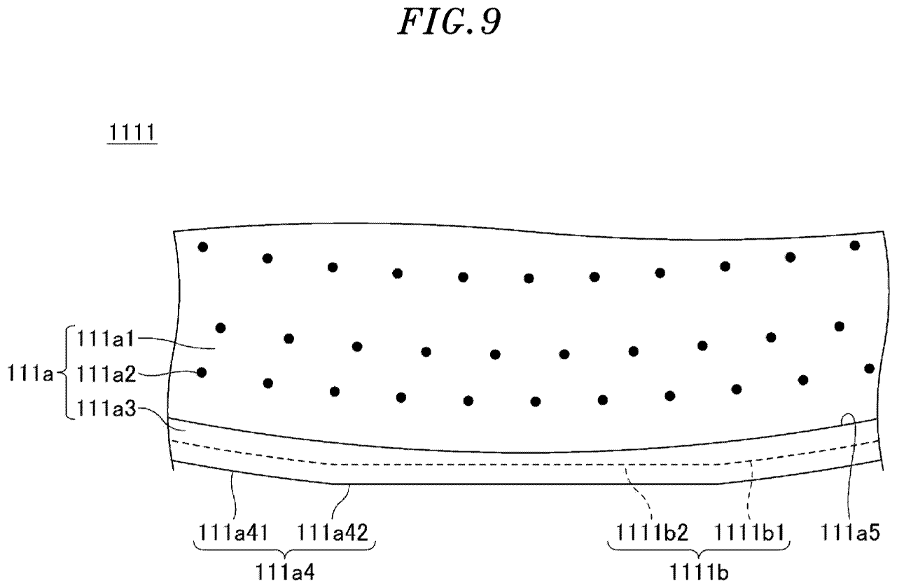

FIG. 9 is an example of a partially enlarged top view of the electrostatic chuck 1111 according to the first embodiment.

In plan view, the outer peripheral edge of the electrostatic electrode 1111b has a circular arc portion 1111b1 and a linear portion 1111b2. In plan view, the linear portion 1111b2 extends linearly between the cutout portion 111a42 of the outer circumferential wall 111a4 and the inner circumferential wall 111a5. Accordingly, the radial distance between the outer peripheral edge of the electrostatic electrode 1111b and the outer circumferential wall 111a4 of the annular protrusion 111a3 is constant over the entire circumference. In other words, the thickness (the horizontal thickness of the intermediate annular ceramic member 1111a2 shown in FIG. 3) of the ceramic member 1111a from the outer peripheral edge of the electrostatic electrode 1111b to the outer circumferential wall 111a4 of the annular protrusion 111a3 is constant. Further, the radial distance between the outer peripheral edge of the electrostatic electrode 1111b and the outer circumferential wall 111a4 of the annular protrusion 111a3 is preferably within a range of 0.1 mm to 5.0 mm. Accordingly, the insulation of the electrostatic electrode 1111b can be ensured. In one embodiment, the radial distance between the cutout portion 111a42 of the outer circumferential wall 111a4 and the outer peripheral edge of the electrostatic electrode (chuck electrode layer) 1111b in plan view is less than the radial distance between the circular arc portion 111a41 of the outer circumferential wall 111a4 and the outer peripheral edge of the ceramic member (dielectric layer) 1111a.

The configuration of the electrostatic chuck 1111 is not limited to the configuration shown in FIGS. 2 and 9.

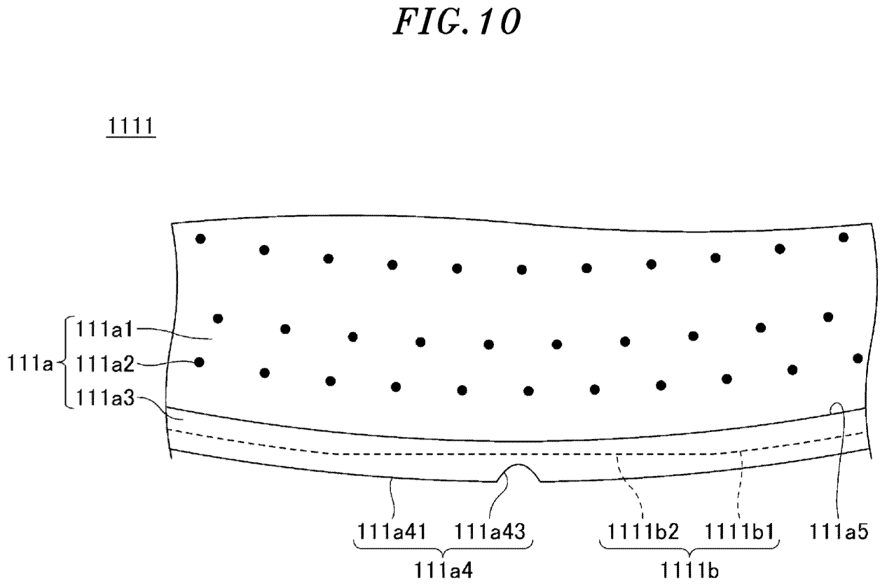

FIG. 10 is an example of a partially enlarged top view of the electrostatic chuck 1111 according to a second embodiment.

The outer circumferential wall 111a4 has the circular arc portion 111a41, which is a part of a circle in plan view, and a cutout portion (notch portion) 111a43 that is cut out from the circle in plan view. Here, the substrate W has a notch for indicating the crystal orientation. Therefore, in the example shown in FIG. 10, the cutout portion 111a43 that is cut out inward from the circle in plan view is formed at the outer peripheral portion of the substrate supporting surface that supports the substrate W to correspond to the notch of the substrate W. Further, the outer peripheral edge of the electrostatic electrode 1111b has the circular arc portion 1111b1 and the linear portion 1111b2 in plan view. Further, the distance between the outer peripheral edge of the electrostatic electrode 1111b and the outer circumferential wall 111a4 of the annular protrusion 111a3 is preferably 0.1 mm or more and 5.0 mm or less. Accordingly, the insulation of the electrostatic electrode 1111b can be ensured. The other configurations are the same as those of the electrostatic chuck 1111 according to the first embodiment shown in FIG. 2 and FIG. 9, so that the redundant description thereof will be omitted.

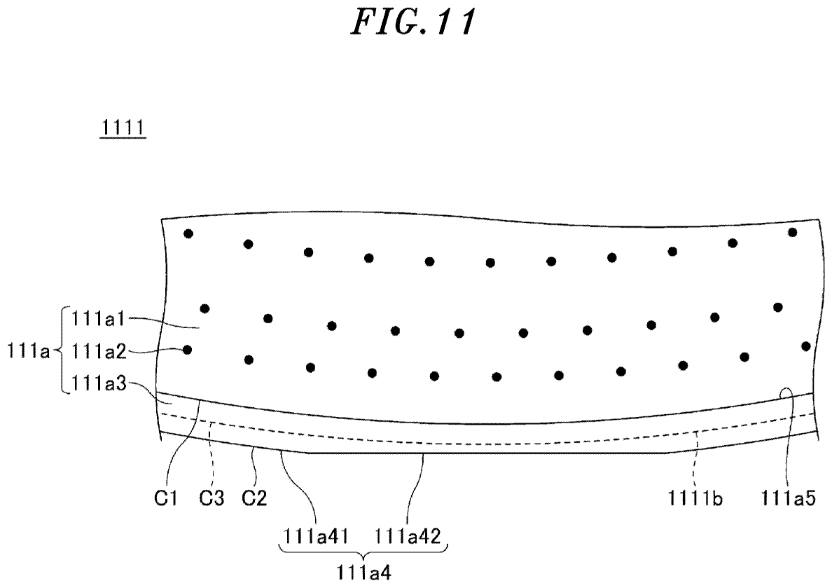

FIG. 11 is an example of a partially enlarged top view of the electrostatic chuck 1111 according to a third embodiment.

The outer peripheral edge of the electrostatic electrode 1111b is formed in a circular shape over the entire circumference in plan view. In other words, the outer peripheral edge of the electrostatic electrode (chuck electrode layer) 1111b extends over the entire circumference along a third circle C3 between the first circle C1 and the second circle C2 in plan view. Accordingly, the radial distance between the outer peripheral edge of the electrostatic electrode 1111b and the inner circumferential wall 111a5 of the annular protrusion 111a3 is constant over the entire circumference. In other words, the width of the overlap between the upper surface of the annular protrusion 111a3 and the electrostatic electrode 1111b is constant over the entire circumference in plan view. The distance between the outer peripheral edge of the electrostatic electrode 1111b and the inner periphery wall 111a5 of the annular projection 111a3 is preferably within a range of 0 mm to 10.0 mm. Further, the radial distance between the outer peripheral edge of the electrostatic electrode 1111b and the cutout portion 111a42 of the outer periphery wall 111a4 of the annular projection 111a3 is preferably 0.1 mm or more. Accordingly, the insulation of the electrostatic electrode 1111b can be ensured. The other configurations are the same as those of the electrostatic chuck 1111 according to the first embodiment shown in FIGS. 2 and 9, so that the redundant description thereof will be omitted.

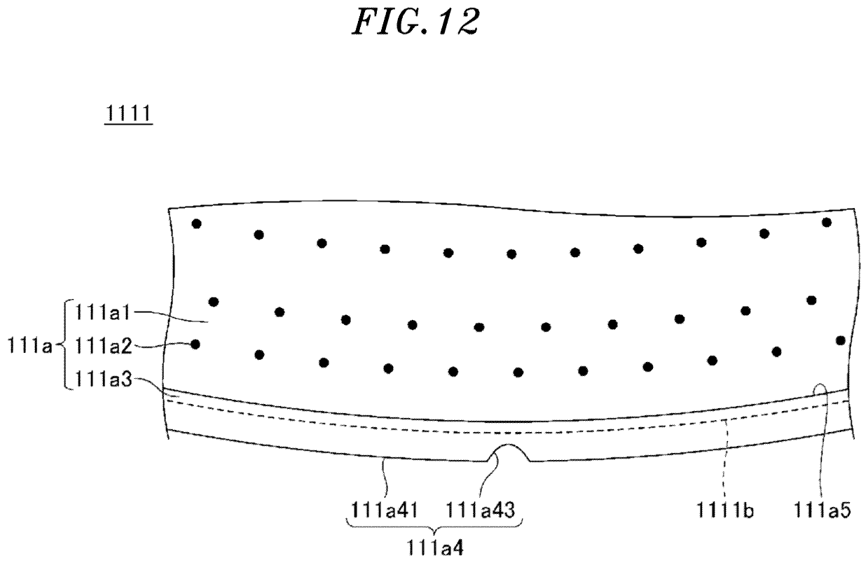

FIG. 12 is an example of a partially enlarged top view of the electrostatic chuck 1111 according to a fourth embodiment.

The outer circumferential wall 111a4 has the circular arc portion 111a41, which is a part of a circle in plan view, and a cutout portion 111a43 that is cut out from the circle in plan view. The outer peripheral edge of the electrostatic electrode 1111b is formed in a circular shape over the entire circumference in plan view. Accordingly, the distance between the outer peripheral edge of the electrostatic electrode 1111b and the inner circumferential wall 111a5 of the annular protrusion 111a3 is constant. In other words, the overlapping width between the upper surface of the annular protrusion 111a3 and the electrostatic electrode 1111b is constant in plan view. Hence, the electrostatic chuck 1111 can attract the outer edge of the backside of the substrate W and suppress leakage of the heat transfer gas. The other configurations are the same as those of the electrostatic chuck 1111 according to the first embodiment shown in FIGS. 2 and 9, so that the redundant description thereof will be omitted.

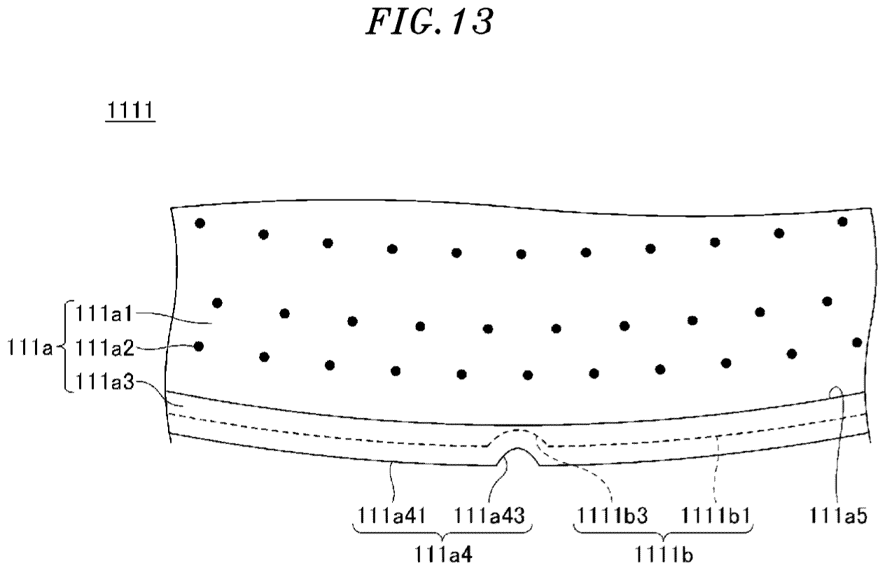

FIG. 13 is an example of a partially enlarged top view of an electrostatic chuck 1111 according to a fifth embodiment.

The outer circumferential wall 111a4 has the circular arc portion 111a41, which is a part of a circle in plan view, and a cutout portion 111a43 that is cut out from the circle in plan view. Further, the outer peripheral edge of the electrostatic electrode 1111b has the circular arc portion 1111b1 and the cutout portion 1111b3 in plan view. Therefore, the distance between the outer peripheral edge of the electrostatic electrode 1111b and the outer circumferential wall 111a4 of the annular protrusion 111a3 is constant. In other words, the thickness of the ceramic member 1111a from the outer peripheral edge of the electrostatic electrode 1111b to the outer circumferential wall 111a4 of the annular protrusion 111a3 is constant. The distance between the outer peripheral edge of the electrostatic electrode 1111b and the outer circumferential wall 111a4 of the annular protrusion 111a3 is preferably 0.1 mm or more and 5.0 mm or less. Accordingly, the insulation of the electrostatic electrode 1111b can be ensured. The other configurations are the same as those of the electrostatic chuck 1111 according to the first embodiment shown in FIGS. 2 and 9, so that the redundant description thereof will be omitted.

The above-described embodiments include the following aspects, for example.

### Appendix 1

An electrostatic chuck comprising:
a dielectric layer having a substrate supporting surface, the substrate supporting surface having a plurality of dot-shaped protrusions and an annular protrusion surrounding the plurality of dot-shaped protrusions, the annular protrusion having an inner circumferential wall and an outer circumferential wall, the inner circumferential wall extending over an entire circumference along a first circle in plan view, the outer circumferential wall having a circular arc portion extending along a part of a second circle lager than the first circle in plan view, and a cutout portion extending linearly between both ends of the circular arc portion in plan view; and
a chuck electrode layer disposed in the dielectric layer to overlap the annular protrusion over an entire circumference in plan view.

### Appendix 2

The electrostatic chuck of Appendix 1, wherein the annular protrusion has a first width from the outer circumferential wall to the inner circumferential wall at the circular arc portion.

### Appendix 3

The electrostatic chuck of Appendix 2, wherein the annular protrusion has a second width from the outer circumferential wall to the inner circumferential wall at a central region of the cutout portion.

### Appendix 4

The electrostatic chuck of Appendix 3, wherein the width of the annular protrusion gradually decreases from an outer region of the cutout portion to the central region of the cutout portion.

### Appendix 5

The electrostatic chuck of Appendix 4, wherein the first width is within a range of 1 to 10 times the second width.

### Appendix 6

The electrostatic chuck of any one of Appendices 2 to 5, wherein the first width is within a range of 1 mm to 10 mm.

### Appendix 7

The electrostatic chuck of any one of Appendices 1 to 6, wherein an outer peripheral edge of the chuck electrode layer has a linear portion extending linearly between the cutout portion of the outer circumferential wall and the inner circumferential wall in plan view.

### Appendix 8

The electrostatic chuck of Appendix 7, wherein a radial distance between the outer peripheral edge of the chuck electrode layer and the outer circumferential wall of the annular protrusion is constant over the entire circumference in plan view.

### Appendix 9

The electrostatic chuck of Appendix 7 or 8, wherein the radial distance between the outer peripheral edge of the chuck electrode layer and the outer circumferential wall of the annular protrusion in plan view is within a range of 0.1 mm to 5 mm.

### Appendix 10

The electrostatic chuck of any one of Appendices 7 to 9, wherein a radial distance between the cutout portion of the outer circumferential wall and the outer peripheral edge of the chuck electrode layer in plan view is smaller than a radial distance between the circular arc portion of the outer circumferential wall and the outer peripheral edge of the chuck electrode layer.

### Appendix 11

The electrostatic chuck of any one of Appendices 1 to 6, wherein the outer peripheral edge of the chuck electrode layer extends over an entire circumference along a third circle between the first circle and the second circle in plan view.

### Appendix 12

The electrostatic chuck of Appendix 11, wherein a radial distance between the outer circumferential edge of the chuck electrode layer and the inner circumferential wall of the annular protrusion is constant over the entire circumference in plan view.

### Appendix 13

The electrostatic chuck of Appendix 11 or 12, wherein the radial distance between the outer circumferential edge of the chuck electrode layer and the inner circumferential wall of the annular protrusion in plan view is within a range of 0 mm to 10 mm.

### Appendix 14

The electrostatic chuck of any one of Appendices 11 to 13, wherein a radial distance between the outer circumferential edge of the chuck electrode layer and the cutout portion of the outer circumferential wall of the annular protrusion in the central region of the cutout portion is 0.1 mm or more in plan view.

### Appendix 15

An electrostatic chuck comprising:
a dielectric layer having a substrate supporting surface, the substrate supporting surface having a plurality of dot-shaped protrusions and an annular protrusion surrounding the plurality of dot-shaped protrusions, the annular protrusion having an inner circumferential wall and an outer circumferential wall, the inner circumferential wall extending over an entire circumference along a first circle in plan view, the outer circumferential wall having a circular arc portion extending along a part of a second circle larger than the first circle in plan view, and a notch portion that is cut out inward from the second circle in plan view; and
a chuck electrode layer disposed in the dielectric layer to overlap the annular protrusion over an entire circumference in plan view.

### Appendix 16

A substrate processing apparatus comprising:
the electrostatic chuck described in any one of Appendices 1 to 15.

Further, the present disclosure is not limited to the configuration described in the above embodiments, and other components can be combined with the configuration described in the above embodiments. The above embodiments can be modified without departing from the scope of the present disclosure, and can be appropriately determined according to the form of the application.

This application claims priority to Japanese Patent Application No. 2022-120740 filed on Aug. 16, 2022, the entire contents of which are incorporated herein by reference.

1. An electrostatic chuck comprising:
a dielectric layer having a substrate supporting surface, the substrate supporting surface having a plurality of dot-shaped protrusions and an annular protrusion surrounding the plurality of dot-shaped protrusions, the annular protrusion having an inner circumferential wall and an outer circumferential wall, the inner circumferential wall extending over an entire circumference along a first circle in plan view, the outer circumferential wall having a circular arc portion extending along a part of a second circle lager than the first circle in plan view, and a cutout portion extending linearly between both ends of the circular arc portion in plan view; and
a chuck electrode layer disposed in the dielectric layer to overlap the annular protrusion over an entire circumference in plan view.

2. The electrostatic chuck of claim 1, wherein the annular protrusion has a first width from the outer circumferential wall to the inner circumferential wall at the circular arc portion.

3. The electrostatic chuck of claim 2, wherein the annular protrusion has a second width from the outer circumferential wall to the inner circumferential wall at a central region of the cutout portion.

4. The electrostatic chuck of claim 3, wherein the width of the annular protrusion gradually decreases from an outer region of the cutout portion to the central region of the cutout portion.

5. The electrostatic chuck of claim 4, wherein the first width is within a range of 1 to 10 times the second width.

6. The electrostatic chuck of claim 5, wherein the first width is within a range of 1 mm to 10 mm.

7. The electrostatic chuck of claim 1, wherein an outer peripheral edge of the chuck electrode layer has a linear portion extending linearly between the cutout portion of the outer circumferential wall and the inner circumferential wall in plan view.

8. The electrostatic chuck of claim 7, wherein a radial distance between the outer peripheral edge of the chuck electrode layer and the outer circumferential wall of the annular protrusion is constant over the entire circumference in plan view.

9. The electrostatic chuck of claim 8, wherein the radial distance between the outer peripheral edge of the chuck electrode layer and the outer circumferential wall of the annular protrusion in plan view is within a range of 0.1 mm to 5 mm.

10. The electrostatic chuck of claim 9, wherein a radial distance between the cutout portion of the outer circumferential wall and the outer peripheral edge of the chuck electrode layer in plan view is smaller than a radial distance between the circular arc portion of the outer circumferential wall and the outer peripheral edge of the chuck electrode layer.

11. The electrostatic chuck of claim 1, wherein the outer peripheral edge of the chuck electrode layer extends over an entire circumference along a third circle between the first circle and the second circle in plan view.

12. The electrostatic chuck of claim 11, wherein a radial distance between the outer circumferential edge of the chuck electrode layer and the inner circumferential wall of the annular protrusion is constant over the entire circumference in plan view.

13. The electrostatic chuck of claim 12, wherein the radial distance between the outer circumferential edge of the chuck electrode layer and the inner circumferential wall of the annular protrusion in plan view is within a range of 0 mm to 10 mm.

14. The electrostatic chuck of claim 13, wherein a radial distance between the outer circumferential edge of the chuck electrode layer and the cutout portion of the outer circumferential wall of the annular protrusion in the central region of the cutout portion is 0.1 mm or more in plan view.

15. An electrostatic chuck comprising:
a dielectric layer having a substrate supporting surface, the substrate supporting surface having a plurality of dot-shaped protrusions and an annular protrusion surrounding the plurality of dot-shaped protrusions, the annular protrusion having an inner circumferential wall and an outer circumferential wall, the inner circumferential wall extending over an entire circumference along a first circle in plan view, the outer circumferential wall having a circular arc portion extending along a part of a second circle larger than the first circle in plan view, and a notch portion that is cut out inward from the second circle in plan view; and
a chuck electrode layer disposed in the dielectric layer to overlap the annular protrusion over an entire circumference in plan view.

16. A substrate processing apparatus comprising:
the electrostatic chuck described in claim 1.
